(19) United States
(12) Patent Application Publication
(10) Pub. No.: US 2019/0226081 A1
(43) Pub. Date: Jul. 25, 2019

(54) THIN METAL FILM ASSEMBLY AND MANUFACTURING METHOD OF THE SAME

(71) Applicant: SAMSUNG DISPLAY CO., LTD., YONGIN-SI (KR)

(72) Inventors: JAE HO AHN, Asan-si (KR); Jae Min Shin, Suwon-si (KR); Min Woo Kim, Hwaseong-si (KR); Won Sang Park, Yongin-si (KR); Sang Woo Kim, Seoul (KR); Jung Yong Lee, Daejeon (KR)

(73) Assignee: KOREA ADVANCED INSTITUTE OF SCIENCE AND TECHNOLOGY, Daejeon (KR)

(21) Appl. No.: 16/251,743

(22) Filed: Jan. 18, 2019

(30) Foreign Application Priority Data
Jan. 19, 2018 (KR) 10-2018-0007173

(51) Int. Cl. C23C 16/06; C23C 16/56; B05D 7/24

(52) U.S. Cl. CPC C23C 16/06; B82Y 30/00; B05D 7/24; C23C 16/56

(57) ABSTRACT

A method for manufacturing a thin metal layer assembly includes forming a thin metal layer including nanopatterns on a preliminary substrate. The method includes forming a metal reducing layer by chemically reducing the thin metal layer. The method includes separating the metal reducing layer from the preliminary substrate. The method includes bonding the metal reducing layer to a target substrate.

### CROSS-REFERENCE TO RELATED APPLICATION

This application claims priority to Korean Patent Application No. 10-2018-0007173 filed in the Korean Intellectual Property Office on Jan. 19, 2018, the disclosure of which is incorporated by reference herein in its entirety.

### (a) Technical Field

Exemplary embodiments of the present invention relate to a thin metal layer assembly, and more particularly to a method for manufacturing the same.

### (b) Discussion of Related Art

A device such as a liquid crystal display (LCD), a touch panel, an electroluminescent device, or a thin film photovoltaic cell may include a plurality of electrodes or wires.

As a general transparent electrode, a metal oxide such as an indium doped tin oxide (ITO) may be used, and as an opaque electrode, a thin film made of silver, copper, gold, or a combination thereof may be used.

Such a transparent electrode and opaque electrode may be relatively weak in terms of undesired bending, folding, or stretching. Accordingly, the transparent or opaque electrode might not be applicable to a bendable device, a foldable device, or a stretchable device.

### SUMMARY

An exemplary embodiment of the present invention provides a thin metal layer assembly including a metal reducing layer that is disposed on a target substrate without using an additional adhesive layer, and a method for manufacturing the same.

A method for manufacturing a thin metal layer assembly according to an exemplary embodiment of the present invention includes forming a thin metal layer including nanopatterns on a preliminary substrate. The method includes forming a metal reducing layer by chemically reducing the thin metal layer; separating the metal reducing layer from the preliminary substrate. The method includes bonding the metal reducing layer to a target substrate.

In the forming of the thin metal layer, at least a part of the thin metal layer may be oxidized.

The thin metal layer may be reduced by a vaporized reducing agent.

The reducing agent may include at least one of an aldehyde including hydrazine, hydroxylamine, and formaldehyde, tetrahydroborate including hypophosphites, sulfites, and lithium (Li), tetrahydroborate including sodium (Na), tetrahydroborate including potassium (K), polyhydroxybenzenes including LiAlH₄, hydroquinone, alkyl-substituted hydroquinones, pyrogallol, phenylenediamines, aminophenols, ascorbic acid, ascorbic acid ketals, an ascorbic acid-based material, 3-pyrazolidone, hydroxytetronic acid, hydroxytetronamide, bisnaphthols, sulfonamidophenols, lithium (Li), sodium (Na), or potassium (K).

The thin metal layer may include at least one of lead (Ph), indium (In), tin (Sn), aluminum (Al), silver (Ag), copper (Cu), gold (Au), platinum (Pt), titanium (Ti), iron (Fe), nickel (Ni), cobalt (Co), or a mixture thereof.

The separating the metal reducing layer and the preliminary substrate may include soaking the preliminary substrate and the metal reducing layer in water.

The method for manufacturing the thin metal layer assembly may include moving the separated metal reducing layer to a carrier substrate.

A surface of the carrier substrate may have hydrophobicity.

The carrier substrate may include at least one of polytetrafluoroethylene, polydimethylsiloxane, polyimide, an acryl polymer, a polyethylene terephthalate, poly(methyl methacrylate), or polyurethane acrylate).

The bonding of the metal reducing layer to the target substrate may include pressing the metal reducing layer and the target substrate.

A thin metal layer assembly according to an exemplary embodiment of the present invention includes a metal reducing layer including nanopatterns. A target substrate is in direct contact with the metal reducing layer. A side of the target substrate in direct contact with the metal reducing layer is smooth.

An adhesive layer might not be provided between the metal reducing layer and the target substrate.

At least one of an upper surface and a bottom surface of the metal reducing layer may include a metal-oxidized film.

The metal reducing layer may include a metal in a reduced form.

The metal reducing layer may include at least one of lead (Ph), indium (In), tin (Sn), aluminum (Al), silver (Ag), copper (Cu), gold (Au), platinum (Pt), titanium (Ti), iron (Fe), nickel (Ni), cobalt (Co), or a mixture thereof.

The target substrate may be flexible.

The target substrate may include an organic material or an inorganic material.

The nanopattern may have a length of about 1 μm or less.

A surface of the metal reducing layer may have hydrophilicity.

A surface of the target substrate may have hydrophilicity.

A method for manufacturing a thin metal layer assembly according to an exemplary embodiment of the present invention may include bonding a thin metal layer including nanopatterns to a preliminary substrate. An entire surface of the thin metal layer facing the preliminary substrate may be bonded directly to the preliminary substrate without an adhesive. The method may include forming a metal reducing layer by chemically reducing the thin metal layer while the metal reducing layer is bonded to the preliminary substrate. The method may include separating the metal reducing layer from the preliminary substrate. The method may include positioning the metal reducing layer on a carrier substrate and transferring the metal reducing layer to an area adjacent to a target substrate. The method may include removing the metal reducing layer from the carrier substrate and bonding the metal reducing layer to the target substrate.

According to an exemplary embodiment of the present invention, a thin metal layer assembly of which stability is increased even through the metal thin film assembly is bent, folded, or stretched, is provided. In addition, a relatively low cost and high efficiency method for manufacturing such a thin metal layer is provided.

### BRIEF DESCRIPTION OF THE DRAWINGS

The above and other features of the present invention will become more apparent by describing in detail exemplary embodiments thereof with reference to the accompanying drawings, in which:

FIG. 1 is a flowchart of a method for manufacturing a thin metal layer assembly according to an exemplary embodiment of the present invention.

FIG. 2, FIG. 3, FIG. 4, FIG. 5, and FIG. 6 illustrate a method for manufacturing a thin metal layer assembly according to an exemplary embodiment of the present invention.

FIG. 7 illustrates a thin metal layer assembly manufactured according to an exemplary embodiment of the present invention.

### DETAILED DESCRIPTION OF THE EMBODIMENTS

Exemplary embodiments of the present invention will be described below in more detail with reference to the accompanying drawings. In this regard, the exemplary embodiments may have different forms and should not be construed as being limited to the exemplary embodiments of the present invention described herein.

Like reference numerals may refer to like elements throughout the specification and drawings.

Sizes of elements in the drawings may be exaggerated for clarity of description.

It will be understood that when a component, such as a layer, a film, a region, or a plate, is referred to as being “on” another component, the component may be directly on the other component or intervening components may be present.

As used herein, the phrase “on a plane” or “in a plan view” may refer to viewing a target portion from the top, and the phrase “on a cross-section” may refer to viewing a cross-section formed by vertically cutting a target portion from the side.

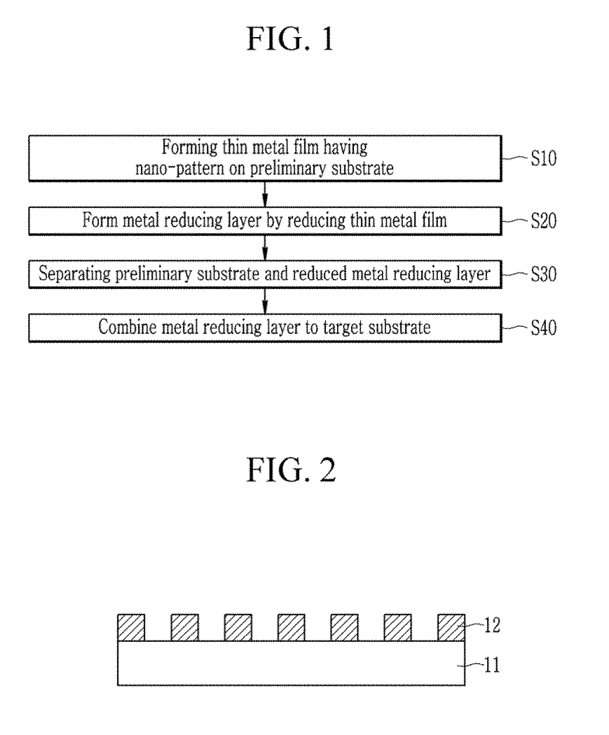

Referring to FIG. 1 to FIG. 6 below, a method for manufacturing a thin metal layer assembly and a thin film assembly manufactured using the same according to an exemplary embodiment of the present invention will be described in more detail.

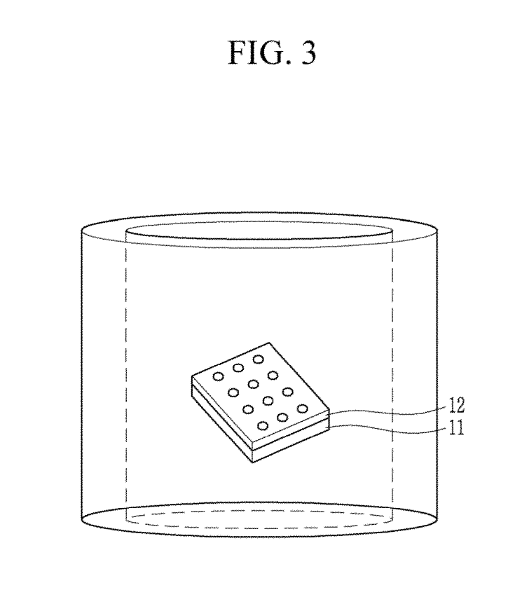

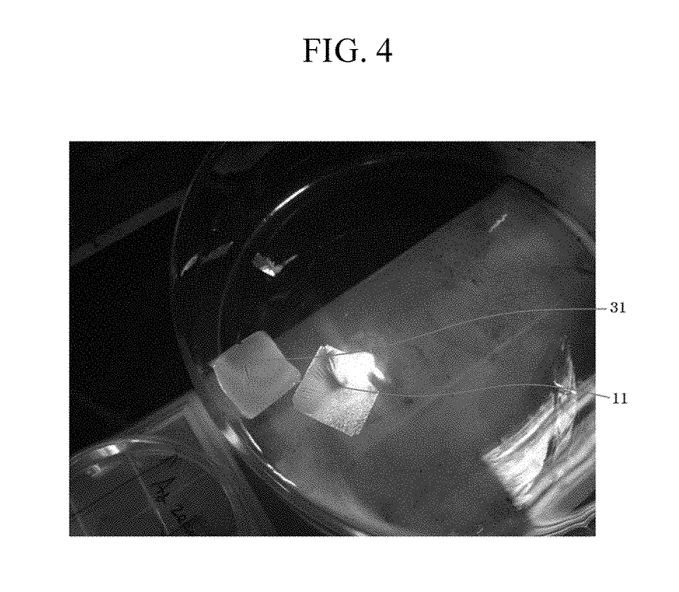

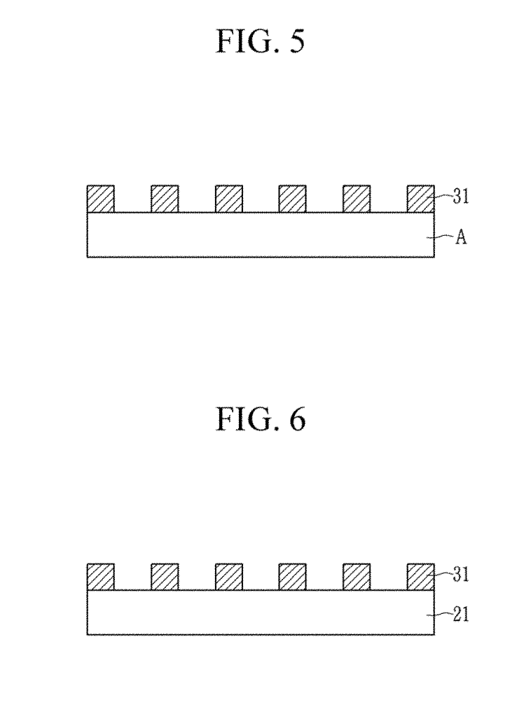

FIG. 1 is a flowchart of a method for manufacturing a thin metal layer assembly according to an exemplary embodiment of the present invention, FIG. 2, FIG. 3, FIG. 4, FIG. 5, and FIG. 6 illustrate a method for manufacturing a thin metal layer assembly according to an exemplary embodiment of the present invention.

Referring to FIG. 1, a method for manufacturing a thin metal layer assembly according to an exemplary embodiment of the present invention may include forming a thin metal layer on a preliminary substrate. For example, a think metal film having a nano-pattern may be formed on a preliminary substrate (510). The method may include forming a metal reducing layer by reducing (e.g., by chemically reducing) the thin metal layer (520). The method may include separating the metal reducing layer and the preliminary substrate (530). The method may include forming a thin metal layer assembly by combining the separated metal reducing layer with a target substrate. For example, the metal reducing layer may be combined with a target substrate (S40).

A method for manufacturing a thin metal layer assembly according to an exemplary embodiment of the present invention will be described in more detail below.

According to a method for manufacturing a thin metal layer assembly according to an exemplary embodiment of the present invention, a thin metal layer 12 that includes nanopatterns (see, e.g., FIG. 2) may be formed on a preliminary substrate 11. An entire surface of the thin metal layer 12 facing the preliminary substrate 11 may be disposed directly on the preliminary substrate 11 without an adhesive. Thus, the thin metal layer 12 may be removed from the preliminary substrate with relatively little force. Additionally, the nanopatterns included in the thin metal layer 12 are less likely to be damaged when an adhesive is omitted. Thus, damage to the nanopatterns, to the thin metal layer 12, and to the preliminary substrate 11 may be prevented.

The thin metal layer 12 may be formed through a deposition process or a coating process on the preliminary substrate 11; however, exemplary embodiments of the present invention are not limited thereto. For example, the thin metal layer 12 formed through the deposition process may include an oxidized form of metal because metal manufactured through the deposition process may be oxidized when contacting air.

The thin metal layer 12 may include at least one of lead (Pb), indium (In), tin (Sn), aluminum (Al), silver (Ag), copper (Cu), gold (Au), platinum (Pt), titanium (Ti), iron (Fe), nickel (Ni), cobalt (Co), or a mixture thereof.

Alternatively, the thin metal layer 12 may include at least one of lead (Pb), indium (In), tin (Sn), aluminum (Al), silver (Ag), copper (Cu), gold (Au), platinum (Pt), titanium (Ti), iron (Fe), nickel (Ni), cobalt (Co), or a mixture thereof and a non-metal.

The thin metal layer 12 may include nanopatterns. The nanopatterns may have any form, and for example, may have a stripe form or a circular form. The nanopatterns may each have a length of about 1 μm or less. For example, the stripe-shaped nanopattern may have a width of about 1 μm or less. For example, the circular-shaped nanopattern may have a diameter of about 1 μm or less.

The nanopattern may be formed, for example, through an etching process or may be formed by depositing a metal on a patterned preliminary substrate. However, exemplary embodiments of the present invention are not limited thereto, and other manufacturing methods may be employed to manufacture the nanopatterns.

A metal reducing layer 31 may be formed by chemically reducing the thin metal layer 12 (e.g., at step S20).

When the thin metal layer 12 is manufactured, a metal included in the thin metal layer 12 may be partially oxidized in the air and thus may be included as an oxidized form in the thin metal layer 12. As the thin metal layer 12 is reduced, the thin metal layer 12 may include a metal in a form in which the metal oxide is reduced again.

In an exemplary embodiment of the present invention, chemical reduction may be performed on a metal included in the thin metal layer 12. The chemical reduction can be performed in various states.

Referring to FIG. 3, the thin metal layer 12 and the preliminary substrate 11 may be put into a vessel, such as a predetermined beaker (e.g., or a crucible), to reduce the thin metal layer 12. The thin metal layer 12 may he reduced by using a reducing agent in the beaker, and for example, a vaporized form of reducing agent can be used. The selected reducing agent may react with the thin metal layer 12 while being vaporized.

In an exemplary embodiment of the present invention, a reducing agent in a vaporized state may be provided by heating the reducing agent in boiling ultrapure water of a predetermined temperature (e.g., from about 70 degrees to about 90 degrees). The reducing agent heated in the boiling ultrapure water may reduce the thin metal layer 12 placed in the same beaker.

However, exemplary embodiments of the present invention are not limited thereto, and the chemical reduction may be performed by using a selected reducing agent in a solution state and then soaking the thin metal layer 12 in the solution.

The reducing agent used in the chemical reduction of the thin metal layer 12 may include at least one of an aldehyde including hydrazine, hydroxylamine, and formaldehyde, tetrahydroborate including hypophosphites, sulfites, and lithium (Li), tetrahydroborate including sodium (Na), tetrahydrohorate including potassium (K), polyhydroxybenzenes including LiAlH₄, hydroquinone, alkyl-substituted hydroquinones, pyrogallol, phenylenediamines, aminophenols, ascorbic acid, ascorbic acid ketals, an ascorbic acid-based material, 3-pyrazolidone, hydroxytetronic acid, hydroxytetronamide, bisnaphthols, sulfonamidophenols, lithium (Li), sodium (Na), or potassium (K).

According to an exemplary embodiment of the present invention, the tetrahydroborate including lithium (Li) is represented as LiBH₄, the tetrahydrohorate including sodium (Na) is represented as NaBH₄, and the tetrahydroborate including potassium (K) is represented as KBH₄.

As an example, a reduction reaction in a case that silver (Ag) is used as the thin metal layer 12 and hydrazine (N₂H₄) is used as the reducing agent according to an exemplary embodiment of the present invention will be described in more detail below; however, exemplary embodiments of the present invention are not limited thereto. In such a manufacturing method, the thin metal layer 12 may be reduced as given in the following reaction equation. In a process for manufacturing the thin metal layer 12, a metal oxide (AgO) included in an oxidized form reacts with the reducing agent (N₂H₄) and thus silver (Ag) in the reduced state may be formed.

2Ag₂O+N₂H₄→4Ag+N₂+2H₂O

According to a method for manufacturing a thin metal layer according to an exemplary embodiment of the present invention, the thin metal layer 12 may be chemically reduced to form the metal reducing layer 31 and then the metal reducing layer 31 may be separated from the preliminary substrate 11 (e.g., at step S30). Thus, as an example, the metal reducing layer 31 might not be removed from the preliminary substrate 11 until after the reduction reaction is completely carried out. For example, the metal reducing layer 31 might not he removed from the preliminary substrate 11 until the metal reducing layer 31 and the preliminary substrate 11 are removed from the vessel described above.

The preliminary substrate 11 and the metal reducing layer 31 may be separated from each other. For example, physical force may be applied to the metal reducing layer 31 to lift it from the preliminary substrate 11 (e.g., after the preliminary substrate 11 and the metal reducing layer 31 are soaked in water, as described in more detail below). However, methods of separating the preliminary substrate 11 and the metal reducing layer 31 are not limited to a particular method, and any known method may be employed. The preliminary substrate 11 and the metal reducing layer 31 can be separated without using an additional medium, or may be separated by soaking the preliminary substrate 11 with the metal reducing layer 31 attached thereto in water. When the preliminary substrate 11 with the metal reducing layer 31 attached thereto is soaked in water, the metal reducing layer 31 may be separated from the preliminary substrate 11 while being floated on water (see, e.g., FIG. 4).

As an example, referring to FIG. 4, when the metal reducing layer 31 is separated from the preliminary substrate 11 while being soaked in water, the metal reducing layer 31 may float on an upper surface of the water.

Referring to FIG. 5, the separated metal reducing layer 31 may be moved to a carrier substrate A. After separating the preliminary substrate 11 and the metal reducing layer 31 by soaking the metal reducing layer 31, the metal reducing layer 31 may he moved to the carrier substrate A. For example, the carrier substrate A may be positioned in a vessel holding water on which the metal reducing layer 31 is floating. Thus, the carrier substrate A may be positioned below the metal reducing layer 31 and lifted through the water to contact a bottom surface of the metal reducing layer 31.

For example, as the carrier substrate A soaked in water is lifted, the metal reducing layer 31 floated on water can be moved to the carrier substrate A.

A surface of the carrier substrate A may have hydrophobicity. The carrier substrate A may include at least one of polytetrafluoroethylene (PTFE), polydimethylsiloxane (PDMS), polyimide (PI), acryl polymer, polyethylene terephthalate (PET), poly(methyl methacrylate) (FMMA), or poly(urethane acrylate).

A surface of the metal reducing layer 31 may have hydrophilicity. A bonding force between the metal reducing layer 31 and the carrier substrate A may be relatively weak because they have different surface properties. Thus, the metal reducing layer 31 can be relatively easily separated from the carrier substrate A. For example, transferring the metal reducing layer 31 using the carrier substrate A may include positioning the metal reducing layer 31 on the carrier substrate A and transferring the metal reducing layer 31 to an area adjacent to the target substrate 21. The method may include removing the metal reducing layer 31 from the carrier substrate A and bonding the metal reducing layer 31 to the target substrate 21.

According to an exemplary embodiment of the present invention, one metal reducing layer 31 may be disposed on one carrier substrate A, but exemplary embodiments of the present invention are not limited thereto. A plurality of metal reducing layers 31 may be arranged by using a Langmuir-Blodgett method, and they may be bonded on the carrier substrate A. Alternatively, the plurality of metal reducing layers 311 may be moved on the carrier substrate A through one process and then transferred to a target substrate 21.

As an example, the metal reducing layer 31 may be moved to the target substrate 21 by using the carrier substrate A in an exemplary embodiment of the present invention, but exemplary embodiments of the present invention are not limited thereto. The separated metal reducing layer 31 may he directly transferred to the target substrate 21.

Referring to FIG. 6, a thin metal layer assembly may be formed by transferring the metal reducing layer 31 to the target substrate 21 (e.g., at step S40). The target substrate 21 may include plastic, paper, an organic material, or an inorganic material, and may be a flexible substrate. In an exemplary embodiment of the present invention, a substrate where the metal reducing layer 31 is transferred may be referred to herein as a target substrate. However, the metal reducing layer 31 may be transferred to any layer or surface, as desired.

For example, the metal reducing layer 31 may be attached to the carrier substrate A by pressing the carrier substrate A on the target substrate 21 to come into direct contact with the metal reducing layer. Thus, during pressing the carrier substrate A on the target substrate 21 the metal reducing layer 31 may be disposed therebetween. Thus, a first surface of the metal reducing layer 31 may be in direct contact with the carrier substrate A, while a second surface of the metal reducing layer 31 opposite the first surface may be in direct contact with the target substrate 21. The carrier substrate A may be pressed on the target substrate 21 by using a roller, but exemplary embodiments of the present invention are not limited thereto, and other known attachment methods may be employed.

When the carrier substrate A is separated from the target substrate 21, the metal reducing layer 31 may remain disposed on the target substrate 21 (see, e.g., FIG. 6). Therefore, a thin film metal assembly may be formed in which no additional adhesive layer is disposed between the target substrate 21 and the metal reducing layer 31 and thus the metal reducing layer 31 may be in direct contact with the target substrate 21.

A surface of the target substrate 21 may have hydrophilicity. The metal reducing layer 31 having the hydrophilic substrate and the target substrate 21 can be relatively strongly bonded to each other, and the metal reducing layer 31 and the carrier substrate A, each having a different property, may be relatively easily separated from each other. For example, the bonding strength between the target substrate 21 and the metal reducing layer 31 may be stronger than the bonding strength between the carrier substrate A and the metal reducing layer 31.

According to an exemplary embodiment of the present invention, a surface of the target substrate 21 in direct contact with the metal reducing layer 31 may be relatively smooth. Since the thin metal layer assembly is formed by transferring the metal reducing layer 31, a pretreatment or post-treatment process for the target substrate 21 may be omitted. When providing the metal reducing layer 31 including nanopatterns, no additional treatment process is performed on the target substrate 21 and thus the target substrate 21 having a smooth surface without damage can be provided. Thus, damage to the target substrate 21 may be prevented, manufacturing yield may be increased, manufacturing costs may be reduced, and process efficiency may be increased. Thus, etching of the target substrate 21 may be prevented.

As an example, at least one of an upper surface or a lower surface of the metal reducing layer 31 may include a metal-oxidized film. As an example, a metal oxide may be formed in the thin metal layer 12, but the metal oxide may be provided again in a metal form in the reducing of the thin metal layer 12. In addition, the upper surface or the lower surface of the metal reducing layer 31 may be exposed to the air during a process for providing the metal reducing layer 31 such that the metal reducing layer 31 may include a metal oxide film in a metal-oxidized form.

Since the metal reducing layer 31 is removed from the carrier substrate A, the carrier substrate A can be reused. Thus, manufacturing yield may be increased, manufacturing costs may be reduced, and process efficiency may be increased. As an example, the metal reducing layer 31 may be completely removed from the carrier substrate A, and thus the carrier substrate A may be reused. Alternatively, if a remaining portion of the metal reducing layer 31 remains adhered to the carrier substrate A, the carrier substrate A may be cleaned to remove the remaining metal reducing layer 31, and thus the carrier substrate A may still be reused.

A method for manufacturing a thin metal layer assembly according to an exemplary embodiment of the present invention may include bonding the thin metal layer 12 including nanopatterns to the preliminary substrate 11. An entire surface of the thin metal layer 12 facing the preliminary substrate 11 may be bonded directly to the preliminary substrate 11 without an adhesive. The method may include forming the metal reducing layer 31 by chemically reducing the thin metal layer 12 while the metal reducing layer 31 is bonded to the preliminary substrate 11. The method may include separating the metal reducing layer 31 from the preliminary substrate 11. The method may include positioning the metal reducing layer 31 on the carrier substrate A and transferring the metal reducing layer 31 to an area adjacent to the target substrate 21. The method may include removing the metal reducing layer 31 from the carrier substrate A and bonding the metal reducing layer 31 to the target substrate 21. Thus, the metal reducing layer 31 including the nanopatterns may be bonded to the target substrate 21 without using any additional adhesive, and the metal reducing layer 31 may be manufactured before being transferred to the target substrate 21. Thus, damage to the target substrate 21 may be prevented, manufacturing yield may be increased, manufacturing costs may be reduced, and process efficiency may be increased. Thus, etching of the target substrate 21 may be prevented.

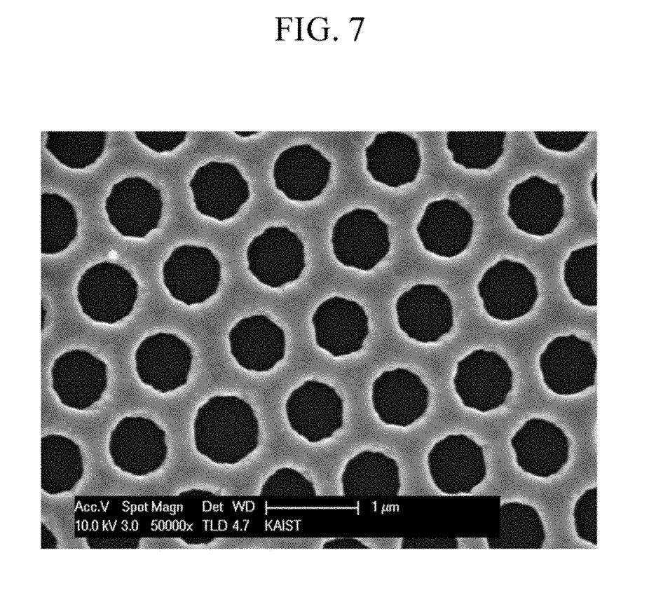

Referring to FIG. 7, a thin metal layer assembly manufactured according to a method for manufacturing a thin metal layer assembly according to an exemplary embodiment of the present invention will be described in more detail below. FIG. 7 illustrates a thin metal layer assembly manufactured according to an exemplary embodiment of the present invention.

Referring to FIG. 7, the thin metal layer assembly may include a metal reducing layer transferred to a target substrate, and therefore the metal reducing layer including nanopatterns can be disposed on a target substrate without damage to the target substrate. In addition, the metal reducing layer and the preliminary substrate can be relatively easily separated from each other, and thus the nanopatterns included in the metal reducing layer can be provided without damage.

Since the metal reducing layer including a plurality of nanopatterns can be bonded to the target substrate without using an additional adhesive layer, the metal reducing layer can be manufactured through a relatively simple process and the metal reducing layer can be arranged without any limitation. In addition, the target substrate can be prevented from being damaged by transferring an already patterned metal reducing layer to the target substrate rather than etching the target substrate.

According to an exemplary embodiment of the present invention, the thin metal layer assembly may include a plurality of nanopatterns and thus the thin metal layer assembly may have increased flexibility. Therefore, the thin metal layer having increased flexibility may be employed in a flexible display device.

While the present invention has been shown and described with reference to the exemplary embodiments thereof, it will be apparent to those of ordinary skill in the art that various changes in form and detail may be made thereto without departing from the spirit and scope of the present invention.

What is claimed is:

1. A method for manufacturing a thin metal layer assembly, comprising:
forming a thin metal layer including nanopatterns on a preliminary substrate;
forming a metal reducing layer by chemically reducing the thin metal layer;
separating the metal reducing layer from the preliminary substrate; and
bonding the metal reducing layer to a target substrate.

2. The method for manufacturing the thin metal layer assembly of claim 1, wherein, in the forming of the thin metal layer, at least a part of the thin metal layer is oxidized.

3. The method for manufacturing the thin metal layer assembly of claim 1, wherein the thin metal layer is reduced by a vaporized reducing agent.

4. The method for manufacturing the thin metal layer assembly of claim 3, wherein the vaporized reducing agent includes at least one of an aldehyde including hydrazine, hydroxylamine, and formaldehyde, tetrahydroborate including hypophosphites, sulfites, and lithium (Li), tetrahydroborate including sodium (Na), tetrahydroborate including potassium (K), polyhydroxybenzenes including LiAlH₄, hydroquinone, alkyl-substituted hydroquinones, pyrogallol, phenylenediamines, aminophenols, ascorbic acid, ascorbic acid ketals, an ascorbic acid-based material, 3-pyrazolidone, hydroxytetronic acid, hydroxytetronamide, bisnaphthols, sulfonamidophenols, lithium (Li), sodium (Na), or potassium (K).

5. The method for manufacturing the thin metal layer assembly of claim 1, wherein the thin metal layer includes at least one of lead (Tab), indium (In), tin (Sn), aluminum (Al), silver (Ag), copper (Cu), gold (Au), platinum (Pt), titanium (Ti), iron (Fe), nickel (Ni), cobalt (Co), or a mixture thereof.

6. The method for manufacturing the thin metal layer assembly of claim 1, wherein the separating the metal reducing layer and the preliminary substrate includes soaking the preliminary substrate and the metal reducing layer in water.

7. The method for manufacturing the thin metal layer assembly of claim 1, further comprising moving the separated metal reducing layer to a carrier substrate.

8. The method for manufacturing the thin metal layer assembly of claim 7, wherein a surface of the carrier substrate has hydrophobicity.

9. The method for manufacturing the thin metal layer assembly of claim 7, wherein the carrier substrate comprises at least one of polytetrafluoroethylene, polydimethyisiloxane, polyimide, an acryl polymer, a polyethylene terephthalate, poly(methyl methacrylate), or poly(urethane acrylate).

10. The method for manufacturing the thin metal layer assembly of claim 1, wherein the bonding of the metal reducing layer to the target substrate comprises pressing the metal reducing layer and the target substrate.

11. A thin metal layer assembly comprising:
a metal reducing layer including nanopatterns; and
a target substrate in direct contact with the metal reducing layer,
wherein a side of the target substrate in direct contact with the metal reducing layer is smooth.

12. The thin metal layer assembly of claim 11, wherein an adhesive layer is not provided between the metal reducing layer arid the target substrate.

13. The thin metal layer assembly of claim 11, wherein at least one of an upper surface and a bottom surface of the metal reducing layer comprises a metal-oxidized film.

14. The thin metal layer assembly of claim 13, wherein the metal reducing layer comprises a metal in a reduced form.

15. The thin metal layer assembly of claim 11, wherein the metal reducing layer comprises at least one of lead (Pb), indium (In), tin (Sn), aluminum (Al), silver (Ag), copper (Cu), gold (Au), platinum (Pt), titanium (Ti), iron (Fe), nickel (Ni), cobalt (Co), or, a mixture thereof.

16. The thin metal layer assembly of claim 11, wherein the target substrate is flexible.

17. The thin metal layer assembly of claim 11, wherein the target substrate comprises an organic material or an inorganic material.

18. The thin metal layer assembly of claim 11, wherein the nanopatterns each have a length of about 1 μm or less.

19. The thin metal layer assembly of claim 11, wherein a surface of the metal reducing layer has hydrophilicity.

20. The thin metal layer assembly of claim 11, wherein a surface of the target substrate has hydrophilicity.
